(19) United States
(12) Patent Application Publication
(10) Pub. No.: US 2022/0310412 A1
(43) Pub. Date: Sep. 29, 2022

(54) GAS CIRCULATION STRUCTURE OF EQUIPMENT FRONT END MODULE (EFEM)

(71) Applicant: RORZE TECHNOLOGY INCORPORATED, New Taipei City (TW)

(72) Inventors: Jen-Wei Chang, New Taipei City (TW); Chung-Hsien Lu, New Taipei City (TW); Cheng-Hsiang Lu, New Taipei City (TW)

(21) Appl. No.: 17/209,237

(22) Filed: Mar. 23, 2021

(51) Int. Cl. H01L 21/67; B01D 46/00

(52) U.S. Cl. CPC H01L 21/67017; B01D 46/0041; B01D 2279/51

(57) ABSTRACT

A gas circulation structure of an equipment front end module is provided, having a main structure including a chamber, a filter assembly, at least one connection pipeline, at least one wind collection device, at least one first fan, at least one second fan, at least one gas inlet port, at least one gas outlet port, and at least one gas discharge valve. By means of the above structure, gas is introduced through the gas inlet port into the connection pipeline and passes through the first fan to move, through the filter module, into the chamber to be caused by the second fan to return back to the connection pipeline to complete circulation. As such, the time required for filling gas is shortened; gas is caused to converge to thereby enhance the circulation efficiency; noise is reduced; dust is properly blown away; and subsequent service and maintenance is made easy.

### TECHNICAL FIELD OF THE INVENTION

The present invention relates to a gas circulation structure of an equipment front end module, and more particularly to a gas circulation structure of an equipment front end module that shortens the time required for filling gas, converges a gas flow to enhance a circulation efficiency, reduces noise, properly blows away dusts, and is easy to service and maintain.

### DESCRIPTION OF THE PRIOR ART

In the field of semiconductor, to prevent a wafer from being contaminated, an environment of transportation for the wafer must be subject to severe control and management. Firstly, a front opening unified pod (FOUP) is provided to receive and hold the wafer. A transportation device is operated to transport the wafer that is received in the FOUP to an equipment front end module (EFEM) or a wafer sorter in an environment-controlled condition. Generally, a clean gas is constantly introduced to cause gas circulation in an interior of the EFEM in order to keep the wafer in an excellent environment.

However, the following drawbacks exist for a known EFEM during replacement of gas and further improvement is required.

Firstly, the machine itself and a chamber thereof are bulky in size so that it takes a large amount of time for initial filling of gas.

Secondly, the structure is complicated and this makes service and maintenance difficult.

Thirdly, the pipeline in a converging form that is available in the market often leads to generation of noise during blowing and feeding gas.

Fourthly, the pipeline in a converging form that is available in the market would make dust scattering all around if the speed at which gas is blown is excessively large and the dust may not be blown away if the blowing speed if excessively slow.

### SUMMARY OF THE INVENTION

The primary objective of the present invention is that a structural arrangement of a wind collection device is provided to make gas flow converging so as to enhance a gas circulation efficiency.

Another objective of the present invention is that a pipeline is made in a form of gradually expanding in order to reduce noise and also to allow dust to be properly blown away by gas.

To achieve the above objectives, the present invention provides a main structure that comprises a chamber, a filter assembly arranged at one side of the chamber, the filter assembly being in communication with the chamber, the chamber being in communication with one end of at least one connection pipeline, an opposite end of the connection pipeline being connected to the filter assembly, the connection pipeline having a pipeline width that is gradually enlarged in a direction from the chamber toward the filter assembly, at least one wind collection device being provided at a connection site between the connection pipeline and the chamber, the wind collection device being provided with at least one first fan, the connection pipeline being provided with at least one second fan, at least one gas inlet port and at least one gas outlet port being provided at one side of the connection pipeline, at least one gas discharge valve being provided on the connection pipeline at a location adjacent to the gas outlet port.

With the above structure, in attempt to use the present invention, a user first pumps gas through the gas inlet port into the connection pipeline to allow the gas to be blown, by means of the structural arrangement of the first fan, into the filter assembly to be subject to filtration to then enter the chamber. Afterwards, the second fan of the wind collection device blows the gas inside the chamber back into the connection pipeline to achieve an effect of circulation by means of the first fan again so that the gas is repeatedly flowing in the equipment front end module. To discharge or evacuate the gas, the gas discharge valve is operated to allow the gas inside the connection pipeline to flow out through the gas outlet port and, further, new gas is introduced through the gas inlet port to thereby achieve the purpose of replacing the gas in the interior.

The equipment front end module according to the present invention is used to keep and preserve a wafer, and by means of the structure and operation described above, the environment in which the wafer is kept can keep circulating and flowing of the gas, and also shortening the time required for filling the gas, and the wind collection device can be used to make gas flow converging to thereby enhance the circulation efficiency, reduce noise, and also to properly blow away dusts and achieve an effect of easing service and maintenance.

### BRIEF DESCRIPTION OF THE DRAWINGS

FIG. 1 is a perspective view, in a see-through form, showing a first preferred embodiment of the present invention.

FIG. 2 is a front view of the first preferred embodiment of the present invention.

FIG. 3 is a first schematic view demonstrating circulation in the first preferred embodiment of the present invention.

FIG. 4 is a second schematic view demonstrating circulation in the first preferred embodiment of the present invention.

FIG. 5 is a third schematic view demonstrating circulation in the first preferred embodiment of the present invention.

FIG. 6 is a fourth schematic view demonstrating circulation in the first preferred embodiment of the present invention.

FIG. 7 is a perspective view, in a see-through form, showing a second preferred embodiment of the present invention.

FIG. 8 is a perspective view, in a see-through form of a portion, showing a third preferred embodiment of the present invention.

FIG. 9 is a perspective view, in a see-through form, showing a fourth preferred embodiment of the present invention.

FIG. 10 is a perspective view, in a see-through form, showing a fifth preferred embodiment of the present invention.

FIG. 11 is a perspective view, in a see-through form and taken from a different angle, showing the fifth preferred embodiment of the present invention.

### DETAILED DESCRIPTION OF THE PREFERRED EMBODIMENT

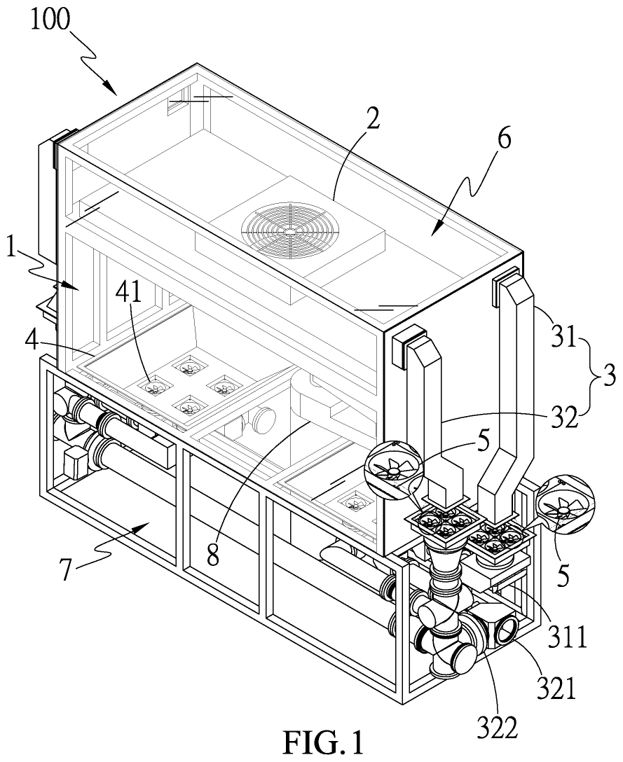

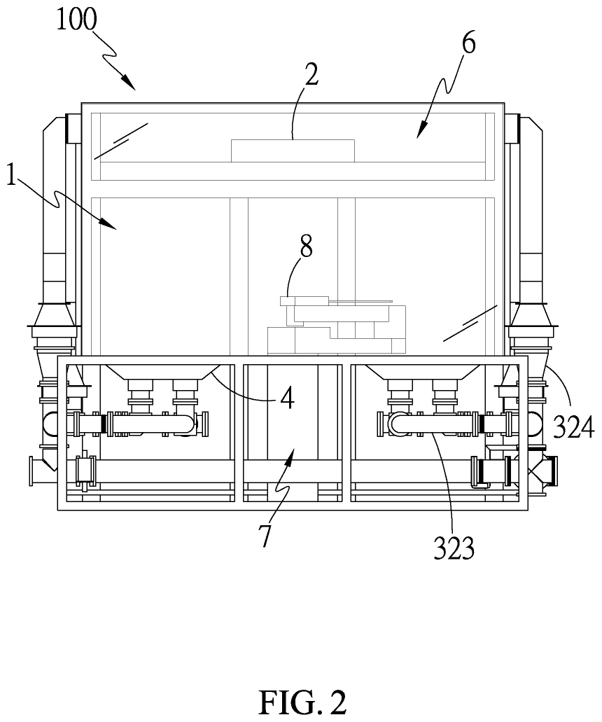

Referring to FIGS. 1 and 2, which are respectively a perspective view, in a see-through form, showing a first preferred embodiment of the present invention and a front view of the first preferred embodiment of the present invention, it can be clearly seen from the drawings that the present invention comprises:

a chamber 1;

a filter assembly 2, the filter assembly 2 being arranged at one side of the chamber 1 and in communication with the chamber 1;

at least one connection pipeline 3, the connection pipeline 3 having an end in communication with the chamber 1 and an opposite end connected to the filter assembly 2 to convey gas from the chamber 1 into the filter assembly 2, the connection pipeline 3 having a pipeline width that is gradually diverging in a direction from the chamber 1 toward the filter assembly 2;

at least one wind collection device 4, the wind collection device 4 being arranged at a connection site between the connection pipeline 3 and the chamber 1;

at least one first fan 5, the first fan 5 being arranged on the connection pipeline 3;

at least one second fan 41, the second fan 41 being arranged in the wind collection device 4;

at least one gas inlet port 311, the gas inlet port 311 being arranged at one side of the connection pipeline 3;

at least one gas outlet port 321, the gas outlet port 321 being arranged at one side of the connection pipeline 3; and

at least one gas discharge valve 322, the gas discharge valve 322 being arranged in the connection pipeline 3 and adjacent to the gas outlet port 321.

In the above, the connection pipeline 3 comprises at least one first pipeline 31 and at least one second pipeline 32 located beside the first pipeline 31, the gas inlet port 311 being provided on the first pipeline 31, the gas outlet port 321 and the gas discharge valve 322 being provided on the second pipeline 32.

In the above, a buffering space 6 is formed in the equipment front end module 100, and the buffering space 6 is located at one side of the filter assembly 2 that is opposite to the chamber 1.

In the above, a non-hermetically enclosed area 7 is formed in the equipment front end module 100, and the non-hermetically enclosed area 7 is located at one side of the wind collection device 4 that is opposite to the chamber 1.

In the above, the chamber 1 is provided therein with a transportation device 8.

In the above, the gas inlet port 311 introduces a gas into the first pipeline 31.

Preferably, the filter assembly 2 is a fan filter unit (FFU).

Preferably, as an example for illustration, the number of each of the first pipeline 31, the second pipeline 32, and the wind collection device 4 is two, and the wind collection device 4 is of a form of a hood.

Preferably, as an example for illustration, the number of the first fan 5 is sixteen.

Preferably, as an example for illustration, the number of the second fan 41 is eight.

Preferably, the gas discharge valve 322 is a butterfly valve, which can be one of a pneumatically-driven butterfly valve, an electrically-driven butterfly valve, and a manually-operated butterfly valve, but is not limited thereto. In the instant embodiment, a configuration involving a pneumatically-driven butterfly valve is taken as an example.

Preferably, the second pipeline 32 comprises a beginning section 323 and a diverging section 324 connected to the beginning section, and the diverging section 324 has a pipeline width that is greater than the pipeline width of the beginning section 323. The beginning section is a partial pipeline of the second pipeline 32 that is connected with the wind collection device 4, and the diverging section 324 is a partial pipeline of the beginning section 323 that is distant from the wind collection device 4.

The above description provides an illustration of the structure of the present invention, and based on a collaborative combination of the structure, the time of filling gas can be shortened, the gas flow is made converged to enhance a circulation efficiency, the noise is reduced, dust can be properly blown away, and service and maintenance are made easy. A detailed description will be provided below.

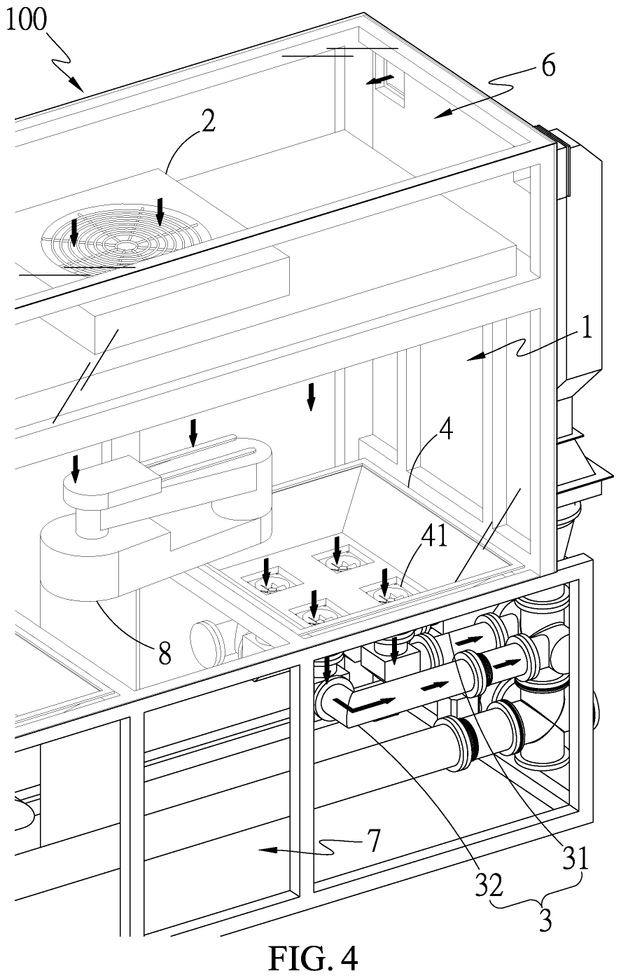

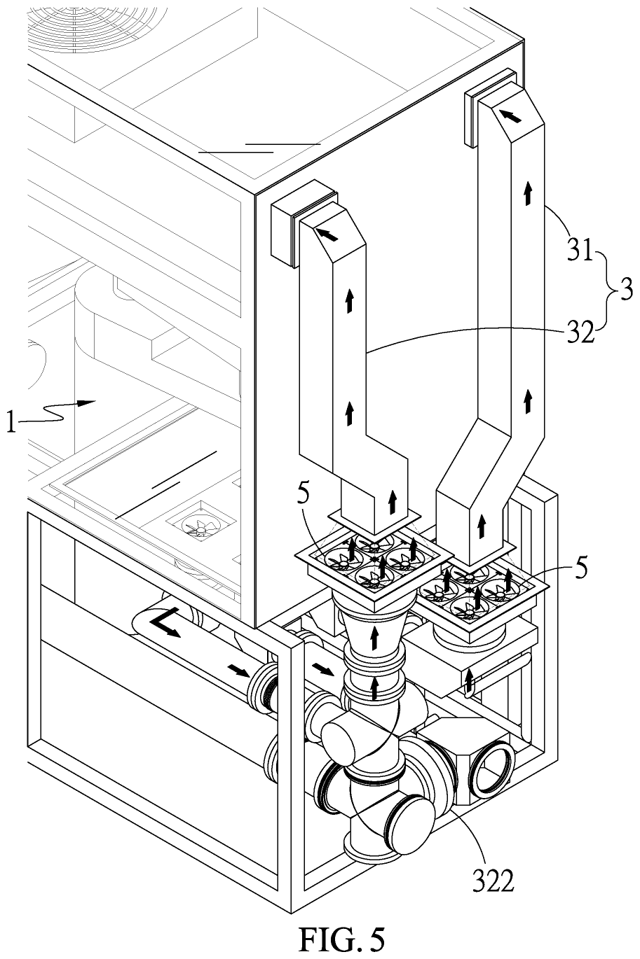

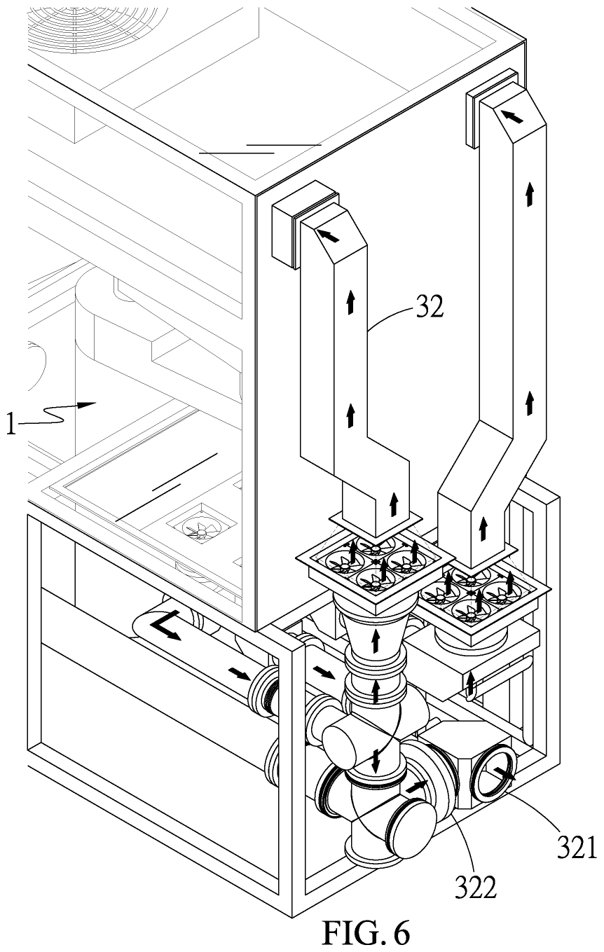

Referring to FIGS. 1-6, which are respectively a perspective view, in a see-through form, showing a first preferred embodiment of the present invention, a front view of the first preferred embodiment of the present invention, a first schematic view demonstrating circulation in the first preferred embodiment of the present invention, a second schematic view demonstrating circulation in the first preferred embodiment of the present invention, a third schematic view demonstrating circulation in the first preferred embodiment of the present invention, and a fourth schematic view demonstrating circulation in the first preferred embodiment of the present invention, it can be clearly seen from the drawings, the equipment front end module 100 mainly functions to receive, hold, and transport a wafer. In order to well keep a precise and delicate component like a wafer, the interior of the equipment front end module 100 must be kept in an excellent environment. Thus, to use the present invention, a gas is firstly supplied through the gas inlet port 311 into the first pipeline 31 of the connection pipeline 3 and the first fan 5 in the first pipeline 31 blows the gas toward the buffering space 6.

The gas that is in the buffering space 6 is subject to adsorption and filtering by the filter assembly 2 and enters the chamber 1 in which the wafer and the transportation device 8 are disposed. The transportation device 8 functions to transport the wafer and the specifics of the structure are not limited. Next, each second fan 41 of the wind collection device 4 simultaneously blows the gas into the first pipeline 31 and the second pipeline 32 to be blown, following the above operation, by the first fan 5 into the buffering space 6 to enter the filter assembly 2 so as to achieve the purpose of circulation of gas.

When the gas in the interior gets saturated or in an attempt to replace the gas in the interior space, the gas discharge valve 322 is operated to allow the gas that flows from the chamber 1 into the second pipeline 32 to flow toward both the gas outlet port 321 and the buffering space 6 to thereby gradually reduce the gas contained in the equipment front end module 100. Simultaneously, fresh gas is pumped into the gas inlet port 311 to thus achieve replacement of the gas contained in the equipment front end module 100 to thereby keep the gas inside the equipment front end module 100 fresh. As such, the wafer can be kept in a good atmosphere.

The gas applied above can be, as an example for illustration, compressed dry air (CDA), nitrogen (N₂) gas, or argon (Ar) gas, for keeping and preserving the wafer, but no limit is imposed thereon.

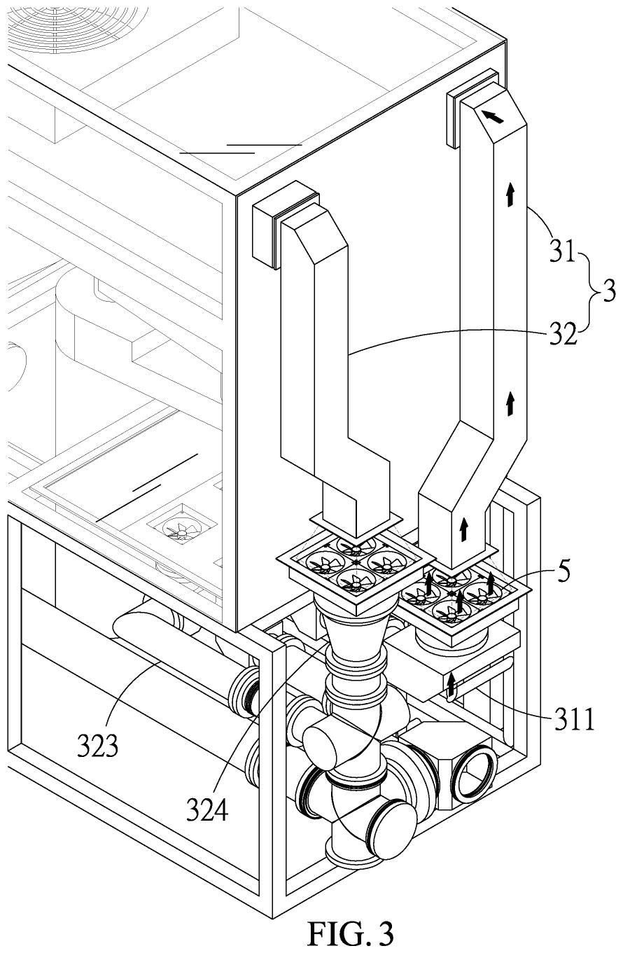

Further, it can be seen from FIGS. 2 and 3, the gas, after passing through the second fan 41 of the wind collection device 4, will sequentially move through the beginning section 323 and the diverging section 324 of the second pipeline 32, and as shown in the drawings, the pipeline width of the diverging section 32 is greater than the pipeline width of the beginning section 323, this more clearly demonstrating an upward diverging configuration of the diverging section 32, reflecting a structure of gradually diverging or expanding of the pipeline width of the connection pipeline 3 in a direction from the chamber 1 toward the filter assembly 2. The pipeline diverging configuration provides an effect of properly blows away dusts. In the instant embodiment, the beginning section 323 and the diverging section 324 provided in the second pipeline 32 is taken as an example, yet it is also applicable to the first pipeline 31 that also belongs to the connection pipeline 3, no limit being imposed thereon.

By means of the structural arrangement of the wind collection device 4, the equipment front end module 100 could establish and include the non-hermetically enclosed area 7. The key feature of the non-hermetically enclosed area 7 is that flowing gas does not flow into the non-hermetically enclosed area 7 and this reduces the space in which gas is flowing. As such, the time required for initial filling of gas can be greatly shortened. Also, since other remaining portions are set in a hermetically enclosed condition, there is no need to provide a sealing member for the non-hermetically enclosed area 7 and an effect of reducing cost may be achieved.

Thus, the structural arrangement of the wind collection device 4 allows shorting of the time for initial filling of gas and makes it possible to not provide an extra sealing member for the non-hermetically enclosed area 7. The diverging arrangement of the first pipeline 31 and the second pipeline 32 makes it possible to prevent noise generated by blowing of gas and allows a user to easily control the flow rate of the gas such that by keeping a proper flow rate of gas, dusts can be properly blown away without causing the dusts inside the connection pipeline 3 to spread all around. The structural arrangement allows a user to easily carry out operations of service and maintenance.

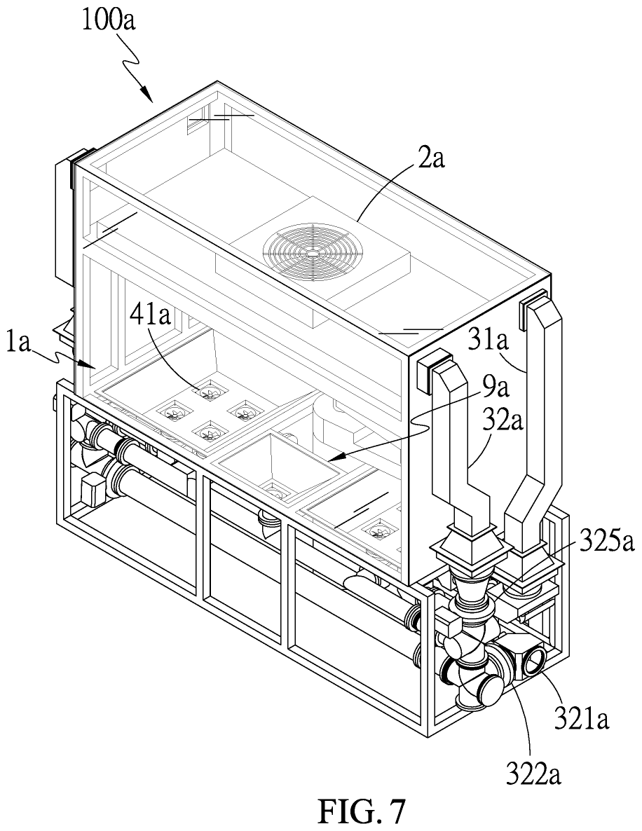

Referring to FIG. 7, which is a perspective view, in a see-through form, showing a second preferred embodiment of the present invention, based on a collaborative combination of the above structure, it can be clearly seen from the drawing that the instant embodiment is generally the same as the previous embodiment and in the instant embodiment, the chamber 1a is provided therein with a wind-collection assisting member 9a, and the wind-collection assisting member 9a has one end connected to the gas discharge valve 322a, and the second pipeline 32a is provided with a pneumatic valve 325a.

Preferably, the wind-collection assisting member 9a is formed of a hood and a fan, and the pneumatic valve 325a is a pneumatically-driven butterfly valve.

By means of the structural arrangement of the wind-collection assisting member 9a, gas that is blown from the filter assembly 2a toward the chamber 1a is simultaneously acted upon by the second fan 41a and the fan of the wind-collection assisting member 9a to simultaneously blow into the first pipeline 31a, the second pipeline 32a, and the gas discharge valve 322a, so that the wind-collection assisting member 9a directly conducts the gas inside the chamber 1a into the gas outlet port 321a to thereby enhance an overall gas replacement rate.

To completely evacuate the gas inside the equipment front end module 100a or to enhance the gas replacement rate, a user may operate the pneumatic valve 325a to close the communication connection between the second pipeline 32a and the filter assembly 2a to allow the gas to be blown by the second fan 41a into the second pipeline 32a to be all conveyed to the gas outlet port 321a for discharging in order to completely evacuate the inside gas or to enhance the gas replacement rate.

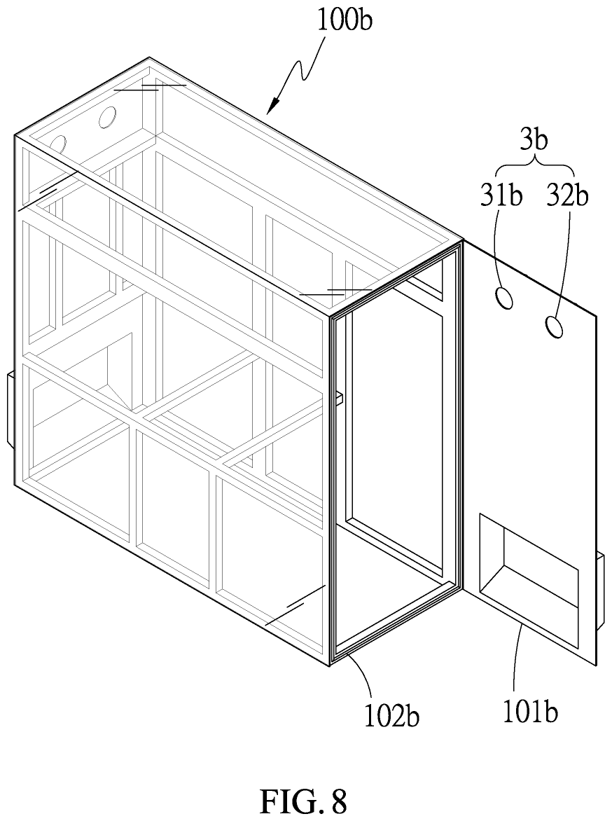

Referring to FIG. 8, which is a perspective view, in a see-through form of a portion, showing a third preferred embodiment of the present invention, based on a collaborative combination of the above structure, it can be clearly seen from the drawing that the instant embodiment is generally the same as the previous embodiments and in the instant embodiment, the equipment front end module 100b is provided with an opening/closing device 101b, and the connection pipeline 3b is mounted on the opening/closing device 101b, and the equipment front end module 100b is provided with a sealing member 102b that corresponds, in position, to the opening/closing device 101b.

Preferably, the opening/closing device 101b is a door panel and the sealing member 102b is a sealing strip.

The instant embodiment is illustrated by removing the remaining portion of the structure and only shows a main body of the equipment front end module 100b, the opening/closing device 101b, and the sealing member 102b. By means of the structural arrangement of the opening/closing device 101b, overall flexibility of use can be enhanced, so that in an attempt to proceed with service and maintenance of the interior of the equipment front end module 100b, it can be performed by simply opening the opening/closing device 101b. In combination with the structural arrangement that, in the connection pipeline 3b, the first pipeline 31b and the second pipeline 32b are provided on the opening/closing device 101b, together with the structural arrangement of the sealing member 102b, it is possible to prevent invading flow of an external gas and also achieving the advantages of the previously-discussed embodiments.

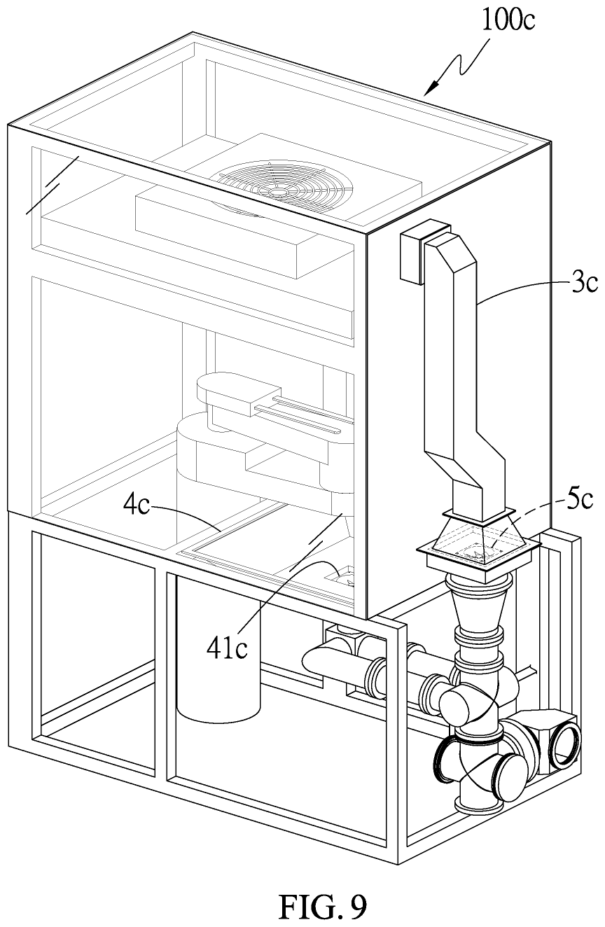

Referring to FIG. 9, which is a perspective view, in a see-through form, showing a fourth preferred embodiment of the present invention, based on a collaborative combination of the above structure, it can be clearly seen from the drawing that the instant embodiment is generally the same as the previous embodiments and in the instant embodiment, the number of each of the connection pipeline 3c, the wind collection device 4c, the first fan 5c, and the second fan 41c is on. As such, when only a limited space is available and it is desired to reduce the size of the equipment front end module 100c, it can be achieved by reducing the number of each of the connection pipeline 3c, the wind collection device 4c, the first fan 5c, and the second fan 41c. It can be clearly seen from FIG. 9 that the reduction of the number of the components allows the size of the equipment front end module 100c to reduced, allowing the present invention to be applied in different conditions of use.

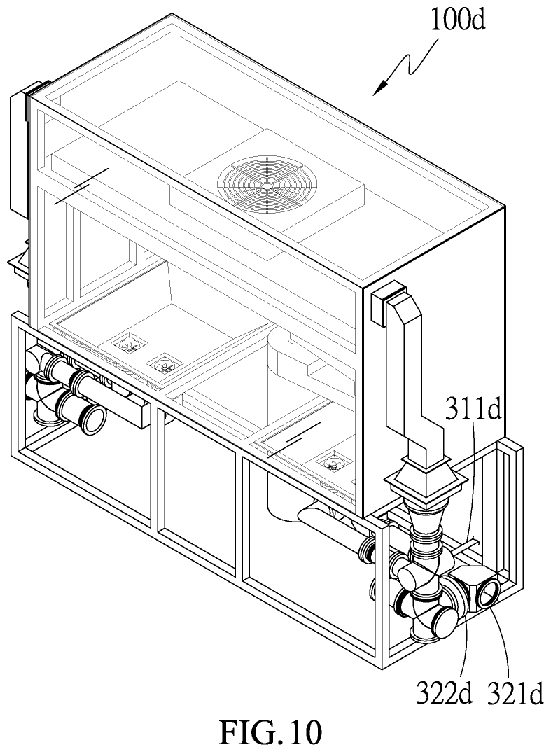

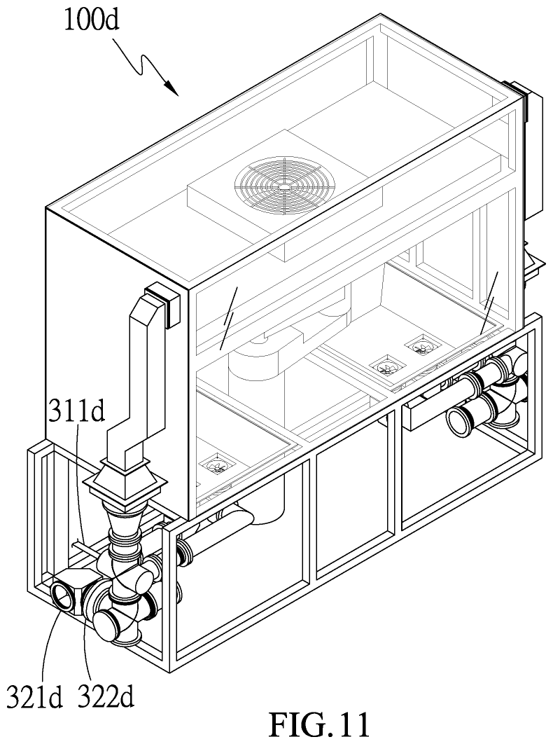

Referring to FIGS. 10 and 11, which are respectively a perspective view, in a see-through form, showing a fifth preferred embodiment of the present invention and a perspective view, in a see-through form and taken from a different angle, showing the fifth preferred embodiment of the present invention, based on a collaborative combination of the above structure, it can be clearly seen from the drawing that the instant embodiment is generally the same as the previous embodiments and in the instant embodiment, the number of each of the gas inlet port 311d, the gas outlet port 321d, and the gas discharge valve 322d is two and are respectively set at two opposite sides of the equipment front end module 100d, and as such, the variation of the number allows the equipment front end module 100d to exhibit a different configuration of embodiment, allowing the present invention to be applied in different conditions of use.

I claim:

1. A gas circulation structure of an equipment front end module, the equipment front end module mainly comprising:
a chamber;
a filter assembly, the filter assembly being arranged at one side of the chamber and in communication with the chamber;
at least one connection pipeline, the connection pipeline having an end in communication with the chamber and an opposite end connected to the filter assembly to convey gas from the chamber into the filter assembly, the connection pipeline having a pipeline width that is gradually diverging in a direction from the chamber toward the filter assembly;
at least one wind collection device, the wind collection device being arranged at a connection site between the connection pipeline and the chamber;
at least one first fan, the first fan being arranged on the connection pipeline;
at least one second fan, the second fan being arranged in the wind collection device;
at least one gas inlet port, the gas inlet port being arranged at one side of the connection pipeline;
at least one gas outlet port, the gas outlet port being arranged at one side of the connection pipeline; and
at least one gas discharge valve, the gas discharge valve being arranged in the connection pipeline and adjacent to the gas outlet port.

2. The gas circulation structure of the equipment front end module according to claim 1, wherein the chamber is provided therein with a wind-collection assisting member, and the wind-collection assisting member has one end connected to the gas discharge valve.

3. The gas circulation structure of the equipment front end module according to claim 1, wherein the connection pipeline is provided with a pneumatic valve.

4. The gas circulation structure of the equipment front end module according to claim 1, wherein a buffering space is formed in the equipment front end module and the buffering space is located at one side of the filter assembly that is distant from the chamber.

5. The gas circulation structure of the equipment front end module according to claim 1, wherein a non-hermetically enclosed area is formed in the equipment front end module and the non-hermetically enclosed area is located at one side of the wind collection device that is distant from the chamber.

6. The gas circulation structure of the equipment front end module according to claim 1, wherein the equipment front end module is provided with an opening/closing device, and the connection pipeline is mounted on the opening/closing device.

7. The gas circulation structure of the equipment front end module according to claim 6, wherein the equipment front end module is provided with a sealing member that corresponds, in position, to the opening/closing device.

8. The gas circulation structure of the equipment front end module according to claim 1, wherein a transportation device is arranged in the chamber.

9. The gas circulation structure of the equipment front end module according to claim 1, wherein the gas inlet port functions to introduce compressed dry air (CDA) or nitrogen (N₂) gas into the connection pipeline.

10. The gas circulation structure of the equipment front end module according to claim 1, wherein the connection pipeline comprises at least one first pipeline, and at least one second pipeline located beside the first pipeline, the gas inlet port being provided on the first pipeline, the gas outlet port and the gas discharge valve being provided on the second pipeline.
